(19) United States
(12) Patent Application Publication
(10) Pub. No.: US 2023/0284394 A1
(43) Pub. Date: Sep. 7, 2023

(54) METHOD FOR PRODUCING WIRING CIRCUIT BOARD

(71) Applicant: NITTO DENKO CORPORATION, Osaka (JP)

(72) Inventors: Naoki SHIBATA, Osaka (JP); Ryosuke SASAOKA, Osaka (JP)

(73) Assignee: NITTO DENKO CORPORATION, Osaka (JP)

(21) Appl. No.: 18/176,900

(22) Filed: Mar. 1, 2023

(30) Foreign Application Priority Data
Mar. 4, 2022 (JP) 2022-033519

(51) Int. Cl. H05K 3/46; G03F 7/039; G03F 7/038

(52) U.S. Cl. CPC H05K 3/4676; G03F 7/039; G03F 7/0387; H05K 3/4608; H05K 3/0023

(57) ABSTRACT

Provided is a method for producing a wiring circuit board capable of improving the dimensional accuracy of a second conductive layer. The wiring circuit board produced by the producing method includes a metal supporting layer, a first insulating layer disposed on one surface of the metal supporting layer in a thickness direction, a first conductive layer disposed on one surface of the first insulating layer in the thickness direction, a second insulating layer disposed on one surface of the first insulating layer in the thickness direction so as to cover the first conductive layer, and a second conductive layer disposed on one surface of the second insulating layer in the thickness direction. The producing method includes a step of forming the second insulating layer by bonding a film made of a photosensitive resin to one surfaces of the first insulating layer and the first conductive layer in the thickness direction.

### CROSS-REFERENCE TO RELATED APPLICATION

The present application claims priority from Japanese Patent Application No. 2022-033519 filed on Mar. 4, 2022, the contents of which are hereby incorporated by reference into this application.

### TECHNICAL FIELD

The present invention relates to a method for producing a wiring circuit board.

### BACKGROUND ART

A method for producing a wiring circuit board including a metal supporting board, a first insulating layer disposed on the upper surface of the metal supporting board, a first conductive layer disposed on the upper surface of the first insulating layer, a second insulating layer disposed on the upper surface of the first insulating layer so as to cover the first conductive layer, and a second conductive layer disposed on the upper surface of the second insulating layer has been known (ref: for example, Patent Document 1 below).

In the producing method described in Patent Document 1, a varnish is applied onto the upper surfaces of the first conductive layer and the first insulating layer to form a photosensitive coating film, and then, the resulting coating film is patterned by exposure and development, thereby forming a second insulating layer.

### CITATION LIST

### Patent Document

Patent Document 1: Japanese Unexamined Patent Publication No. 2009-099687

### SUMMARY OF THE INVENTION

### Problem to be Solved by the Invention

In the producing method of Patent Document 1, since the second insulating layer is formed from the varnish, the second insulating layer has an inclined portion (shoulder portion) corresponding to a corner portion which is formed by the upper surface and the side surface of the first conductive layer.

It is necessary that the second conductive layer is overlapped with the inclined portion depending on the application and purpose of the wiring circuit board. In this case, there is a problem that the dimensional accuracy of the second conductive layer is lowered.

Furthermore, it is also necessary to more easily form the second insulating layer by patterning.

The present invention provides a method for producing a wiring circuit board capable of easily forming a second insulating layer by patterning a film, and improving the dimensional accuracy of a second conductive layer.

### Means for Solving the Problem

The present invention (1) includes a method for producing a wiring circuit board, the wiring circuit board including a metal supporting layer, a first insulating layer disposed on one surface of the metal supporting layer in a thickness direction, a first conductive layer disposed on one surface of the first insulating layer in the thickness direction, a second insulating layer disposed on one surface of the first insulating layer in the thickness direction so as to cover the first conductive layer, and a second conductive layer disposed on one surface of the second insulating layer in the thickness direction, wherein the method includes a step of forming the second insulating layer by bonding a film made of a photosensitive resin to one surfaces of the first insulating layer and the first conductive layer in the thickness direction.

In the producing method, since the film made of the photosensitive resin is bonded to one surfaces of the first insulating layer and the first conductive layer in the thickness direction, it is easy to flatten one surface of the second insulating layer in the thickness direction. Therefore, it is possible to dispose the second conductive layer with respect to the second insulating layer with high dimensional accuracy.

Furthermore, the film made of the photosensitive resin after being bonded to the first insulating layer and the first conductive layer is patterned by exposure and development, and it is possible to easily form the second insulating layer.

The present invention (2) includes the method for producing a wiring circuit board described in (1), wherein in the step of forming the second insulating layer, the film is compressively bonded to the first insulating layer and the first conductive layer.

In the producing method, in the step of forming the second insulating layer, since the film is compressively bonded to the first insulating layer and the first conductive layer, it is possible to reliably flatten one surface of the second insulating layer in the thickness direction.

The present invention (3) includes the method for producing a wiring circuit board described in (1) or (2), wherein the film includes a photosensitive resin layer containing a polyamic acid resin.

In the producing method, it is possible to easily form the second insulating layer including a resin layer made of a polyimide resin from the photosensitive resin layer containing the polyamic acid resin by patterning.

The present invention (4) includes the method for producing a wiring circuit board described in (3), wherein the film further includes a photosensitive adhesive layer made of an adhesive.

In the producing method, since the film further includes the photosensitive adhesive layer made of the adhesive, it is possible to attach the resin layer to the first insulating layer via the photosensitive adhesive layer, and further, it is possible to easily form the second insulating layer by patterning the photosensitive film.

The present invention (5) includes the method for producing a wiring circuit board described in any one of (1) to (4) further including a step of forming the first insulating layer by varnish coating, exposure, and development, or pattern printing.

In the producing method, the first insulating layer is formed by varnish coating, exposure, and development, or pattern printing, and the second insulating layer is formed of the film made of the photosensitive resin. Therefore, since the first insulating layer can be formed thinly, it is possible to decrease the total thickness of the first insulating layer and the second insulating layer.

The present invention (6) includes the method for producing a wiring circuit board described in any one of (1) to (5), wherein the coating film formed by coating, exposure, and development, or pattern printing contains a photosensitive polyamic acid resin.

In the producing method, it is possible to form the first insulating layer made of the polyimide resin from the photosensitive polyamic acid resin.

The present invention (7) includes the method for producing a wiring circuit board described in any one of (1) to (6), wherein the wiring circuit board further includes a third insulating layer disposed on one surface of the second insulating layer in the thickness direction so as to cover the second conductive layer, and the method further includes a step of forming the third insulating layer by varnish coating, exposure, and development, or pattern printing.

Since the third insulating layer is formed by varnish coating, exposure, and development, or pattern printing, and the second insulating layer is formed of the film made of the photosensitive resin, it is possible to thinly form the third insulating layer. Therefore, it is possible to decrease the total thickness of the third insulating layer and the second insulating layer.

The present invention (8) includes the method for producing a wiring circuit board described in (7), wherein a coating film formed by coating, exposure, and development, or pattern printing contains a photosensitive polyamic acid resin.

In the producing method, it is possible to form the third insulating layer made of the polyimide resin from the photosensitive polyamic acid resin.

### Effect of the Invention

In the method for producing a wiring circuit board of the present invention, it is possible to easily form a second insulating layer by patterning the film, and to improve the dimensional accuracy of a second conductive layer.

### BRIEF DESCRIPTION OF THE DRAWINGS

FIGS. 1A to 1G show production process views of one embodiment of a method for producing a wiring circuit board of the present invention:

FIG. 1A illustrating a step [1],

FIG. 1B illustrating a step [2],

FIG. 1C illustrating a step [3],

FIG. 1D illustrating a step [4], and a step [4] of disposing a film in a metal supporting layer, a first insulating layer, and a first conductive layer,

FIG. 1E illustrating a step [4], and a step [4] of forming a second insulating layer,

FIG. 1F illustrating a step [5], and

FIG. 1G illustrating a step [6].

FIGS. 2A to 2C show production process views of a modified example of a method for producing a wiring circuit board of the present invention:

FIG. 2A illustrating a step [4], and a step [4] of disposing a film consisting of a resin layer in a metal supporting layer, a first insulating layer, and a first conductive layer,

FIG. 2B illustrating a step [4], and a step [4] of forming a second insulating layer, and

FIG. 2C illustrating a step [5] and a step [6].

FIG. 3 shows a conventional example of disposing a second conductive layer in a second insulating layer having an inclined portion.

### DESCRIPTION OF EMBODIMENTS

### 1. One Embodiment of Method for Producing Wiring Circuit Board

One embodiment of a method for producing a wiring circuit board of the present invention is described.

1.1 Wiring Circuit Board

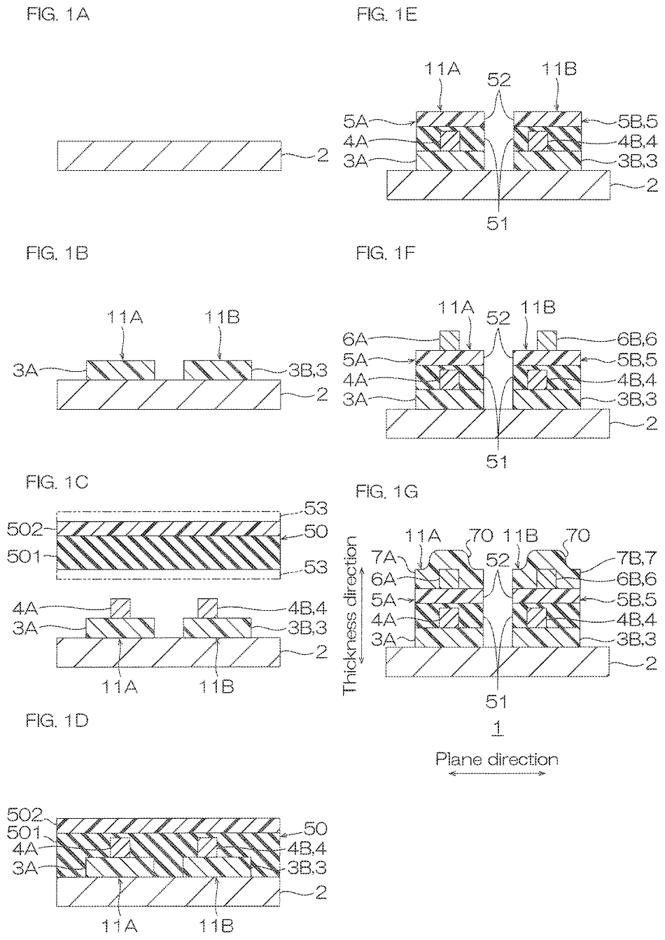

As shown in FIG. 1G, a wiring circuit board 1 obtained by the producing method has a thickness. The wiring circuit board 1 extends in a plane direction. The plane direction is perpendicular to a thickness direction. The wiring circuit board 1 has a plate shape. A thickness of the wiring circuit board 1 is, for example, 10 μm or more, and for example, 500 μm or less, preferably 300 μm or less, more preferably 200 μm or less.

A wiring circuit board 1 includes a metal supporting layer 2, a first insulating layer 3, a first conductive layer 4, a second insulating layer 5, a second conductive layer 6, and a third insulating layer 7. Further, the wiring circuit board 1 includes a plurality of divided bodies 11A and 11B. Each of the divided bodies 11A and 11B is disposed on one side of the metal supporting layer 2 in the thickness direction. The divided bodies 11A and 11B are divided in the plane direction. The divided body 11B is spaced apart from the divided body 11A in the plane direction. As described later, the divided body 11A includes a first insulator 3A, a first wiring 4A, a second insulator 5A, a second wiring 6A, and a third insulator 7A. The divided body 11B includes a first insulator 3B, a first wiring 4B, a second insulator 5B, a second wiring 6B, and a third insulator 7B.

1.1.1 Metal Supporting Layer 2

The metal supporting layer 2 is disposed in the other end portion of the wiring circuit board 1 in the thickness direction. The metal supporting layer 2 forms the other end surface of the wiring circuit board 1 in the thickness direction. The metal supporting layer 2 extends in the plane direction. Each of one surface and the other surface of the metal supporting layer 2 in the thickness direction is a flat surface. The metal supporting layer 2 is in contact with the other surfaces of the divided bodies 11A and 11B in the thickness direction. A material for the metal supporting layer 2 is a metal. Examples of the metal include stainless steel and copper alloys. The thickness of the metal supporting layer 2 is, for example, 10 μm or more, and 1000 μm or less.

1.1.2 First Insulating Layer 3

The first insulating layer 3 is disposed on one surface of the metal supporting layer 2 in the thickness direction. The first insulating layer 3 extends in the plane direction. One surface of the first insulating layer 3 in the thickness direction is a flat surface. The first insulating layer 3 has a pattern shape. Specifically, the first insulating layer 3 includes a plurality of first insulators 3A and 3B. Each of the first insulators 3A and 3B is included in each of the divided bodies 11A and 11B described above. The first insulating layer 3 is referred to as a base insulating layer.

Examples of the material for the first insulating layer 3 include resins. Examples of the resin include polyimide resins, polyamideimide resins, acrylic resins, polyether nitrile resins, polyether sulfone resins, polyethylene terephthalate resins, polyethylene naphthalate resins, and polyvinyl chloride resins. As the material for the first insulating layer 3, preferably, a polyimide resin is used. The thickness of the first insulating layer 3 is, for example, 1 μm or more, preferably 3 μm or more, and for example, 30 μm or less, preferably 20 μm or less.

1.1.3 First Conductive Layer 4

The first conductive layer 4 is disposed on one surface of the first insulating layer 3 in the thickness direction. The first conductive layer 4 extends in the plane direction. In the present embodiment, the first conductive layer 4 has a generally rectangular shape in a cross-sectional view. One surface of the first conductive layer 4 in the thickness direction is a flat surface.

The first conductive layer 4 includes the plurality of first wirings 4A and 4B. Each of the first wirings 4A and 4B is included in each of the divided bodies 11A and 11B described above. Each of the first wirings 4A and 4B extends in a first direction included in the plane direction. In the present embodiment, the first direction is a depth direction in FIG. 1G. Each of the first wirings 4A and 4B is disposed on one surface of each of the first insulators 3A and 3B in the thickness direction. The material for the first conductive layer 4 is a conductor. Examples of the conductor include copper, nickel, gold, and alloys of these. A width of each of the first wirings 4A and 4B is, for example, 5 μm or more, and for example, 250 μm or less. The thickness of the first conductive layer 4 is, for example, 3 μm or more, and for example, 50 μm or less. The width is a length in a direction perpendicular to the first direction and the thickness direction.

1.1.4 Second Insulating Layer 5

The second insulating layer 5 is disposed on one surface of the first insulating layer 3 in the thickness direction so as to cover the first conductive layer 4. Specifically, the second insulating layer 5 is in contact with one surface of the first insulating layer 3 in the thickness direction, one surface of the first conductive layer 4 in the thickness direction, and both end surfaces of the first conductive layer 4 in a width direction. The second insulating layer 5 extends in the plane direction. One surface of the second insulating layer 5 in the thickness direction is a flat surface.

The second insulating layer 5 has a pattern shape. Specifically, the second insulating layer 5 includes the plurality of second insulators 5A and 5B. Each of the second insulators 5A and 5B is included in each of the divided bodies 11A and 11B described above. Each of the second insulators 5A and 5B is disposed on one surface of each of the first insulators 3A and 3B so as to cover each of the first wirings 4A and 4B.

In the present embodiment, the end surface of the second insulating layer 5 in the width direction (each of the second insulators 5A and 5B) is flush with the end surface of the first insulating layer 3 in the width direction (each of the first insulators 3A and 3B). The second insulating layer 5 is referred to as an intermediate insulating layer. The thickness of the second insulating layer 5 is, for example, 3 μm or more, preferably 5 μm or more, and for example, 50 μm or less, preferably 30 μm or less. The total thickness of the first insulating layer 3 and the second insulating layer 5 is, for example, 80 μm or less, preferably 50 μm or less, more preferably 40 μm or less, and 5 μm or more.

1.1.5 Layer Structure of Second Insulating Layer 5

The second insulating layer 5 includes an adhesive layer 51 and a resin layer 52 in order toward one side in the thickness direction.

1.1.6 Adhesive Layer 51

The adhesive layer 51 is disposed in the other end portion of the second insulating layer 5 in the thickness direction. The adhesive layer 51 forms the other surface of the second insulating layer 5 in the thickness direction. In the present embodiment, one surface of the adhesive layer 51 in the thickness direction is a flat surface. The other surface of the adhesive layer 51 in the thickness direction follows the shape of the first conductive layer 4. Specifically, the adhesive layer 51 is in contact with one surface of the first insulating layer 3 in the thickness direction, one surface of the first conductive layer 4 in the thickness direction, and both end surfaces of the first conductive layer 4 in the width direction. The adhesive layer 51 is a photoreceptor of an adhesive to be described later.

Examples of the adhesive include epoxy resin adhesives, phenol resin adhesives, polyester resin adhesives, and acrylic resin adhesives. These may be used alone or in combination of two or more. The adhesive is described in, for example, Japanese Unexamined Patent Publication No. 2012-004523. In the present embodiment, the adhesive does not include a polyimide resin adhesive.

The thickness of the adhesive layer 51 is, for example, 5 μm or more, preferably 10 μm or more, and for example, 45 μm or less, preferably 30 μm or less. A ratio of the thickness of the adhesive layer 51 to the thickness of the second insulating layer 5 is, for example, 0.3 or more, preferably 0.6 or more, and for example, 0.9 or less, preferably 0.8 or less. The thickness of the adhesive layer 51 is a distance in the thickness direction between one surface of the first insulating layer 3 in the thickness direction and one surface of the adhesive layer 51 in the thickness direction.

1.1.7 Resin Layer 52

The resin layer 52 is disposed in one end portion of the second insulating layer 5 in the thickness direction. The resin layer 52 forms one surface of the second insulating layer 5 in the thickness direction. The resin layer 52 is disposed on one surface of the adhesive layer 51 in the thickness direction. In the present embodiment, one surface of the resin layer 52 in the thickness direction is a flat surface. Examples of the resin include resins illustrated in the first insulating layer 3, and preferably, a polyimide resin is used.

The thickness of the resin layer 52 is, for example, 1 μm or more, preferably 3 μm or more, and for example, 45 μm or less, preferably 30 μm or less. The ratio of the thickness of the resin layer 52 to the thickness of the second insulating layer 5 is, for example, 0.1 or more, preferably 0.2 or more, and for example, 0.7 or less, preferably 0.4 or less. The resin layer 52 is preferably thinner than the adhesive layer 51. The ratio of the thickness of the resin layer 52 to the thickness of the adhesive layer 51 is, for example, below 1, preferably 0.9 or less, more preferably 0.5 or less, and for example, 0.01 or more, preferably 0.1 or more. The thickness of the resin layer 52 is a distance in the thickness direction between one surface of the adhesive layer 51 in the thickness direction and one surface of the resin layer 52 in the thickness direction.

1.1.8 Second Conductive Layer 6

The second conductive layer 6 is disposed on one surface of the second insulating layer 5 in the thickness direction. The second conductive layer 6 extends in the plane direction. In the present embodiment, the second conductive layer 6 has a generally rectangular shape in a cross-sectional view. One surface of the second conductive layer 6 in the thickness direction is a flat surface. The second conductive layer 6 includes the plurality of second wirings 6A and 6B. Each of the second wirings 6A and 6B is included in each of the divided bodies 11A and 11B described above. Each of the second wirings 6A and 6B extends in the above-described first direction. Each of the second wirings 6A and 6B is disposed on one surface of each of the second insulators 5A and 5B in the thickness direction.

In the present embodiment, the second wiring 6A is overlapped with the first wiring 4A when projected in the thickness direction. The second wiring 6B has a portion overlapped with the first wiring 4B and a portion not overlapped with the first wiring 4B when projected in the thickness direction. Specifically, the second wiring 6B is not overlapped with the other end surface of the first wiring 4B in the width direction, while being overlapped with one end surface of the first wiring 4B in the width direction when projected in the thickness direction.

Examples of the material for the second conductive layer 6 include conductors illustrated in the first conductive layer 4. Each of the widths of the second wirings 6A and 6B, and the thickness of the second conductive layer 6 are the same as each of the widths of the first wirings 4A and 4B, and the thickness of the first conductive layer 4, respectively.

1.1.9 Third Insulating Layer 7

The third insulating layer 7 is disposed on one surface of the second insulating layer 5 in the thickness direction so as to cover the second conductive layer 6. The third insulating layer 7 forms one surface of the wiring circuit board 1 in the thickness direction. The third insulating layer 7 extends in the plane direction. One surface of the third insulating layer 7 in the thickness direction may include an inclined portion (shoulder portion) 70. The inclined portion 70 corresponds to (faces) a corner portion formed by one surface in the thickness direction and the end surface in the width direction in each of the second wirings 6A and 6B.

The third insulating layer 7 has a pattern shape. Specifically, the third insulating layer 7 includes the plurality of third insulators 7A and 7B. Each of the third insulators 7A and 7B is included in each of the divided bodies 11A and 11B described above. Each of the third insulators 7A and 7B is disposed on one surface of each of the second insulators 5A and 5B so as to cover each of the second wirings 6A and 6B. In the present embodiment, the end surface of the third insulating layer 7 in the width direction (each of the third insulators 7A and 7B) is flush with the end surface of the second insulating layer 5 in the width direction (each of the second insulators 5A and 5B). The third insulating layer 7 is referred to as a cover insulating layer.

The thickness of the third insulating layer 7 is, for example, 1 μm or more, preferably 3 μm or more, and for example, 30 μm or less, preferably 20 μm or less. The thickness of the third insulating layer 7 is a length in the thickness direction of one surface of the second insulating layer 5 in the thickness direction, and one surface of the third insulating layer 7 in the thickness direction facing the above-described one surface without the second conductive layer 6. The total thickness of the third insulating layer 7 and the second insulating layer 5 is, for example, 80 μm or less, preferably 50 μm or less, more preferably 40 μm or less, and for example, 5 μm or more.

1.2 Producing Method

As shown in FIGS. 1A to 1G, a method for producing the wiring circuit board 1 includes steps [1] to [6]. The steps [1] to [6] are carried out in this order.

1.2.1 Step [1]

In the step [1], as shown in FIG. 1A, the metal supporting layer 2 is prepared.

1.2.2 Step [2]

In the step [2], as shown in FIG. 1B, the first insulating layer 3 is formed on one surface of the metal supporting layer 2 in the thickness direction. In the present embodiment, the first insulating layer 3 is formed by varnish coating, exposure, and development, or pattern printing on one surface of the metal supporting layer 2 in the thickness direction.

When the varnish is coated, the varnish contains, for example, a photosensitive agent, a resin component, and a solvent. When the first insulating layer 3 is made of a polyimide resin, the resin component preferably contains an acid dianhydride and a diamine.

The varnish is coated onto the entire one surface of the metal supporting layer 2, and subsequently heated, thereby forming a photosensitive coating film. The coating film contains a polyamic acid resin. The polyamic acid resin is a reactant of the acid dianhydride and the diamine, and a precursor material of a polyimide resin. Subsequently, the coating film is exposed and developed, and, if necessary, heated after exposure, thereby forming the first insulating layer 3 including the first insulators 3A and 3B.

When the varnish is pattern-printed, the varnish contains, for example, the above-described resin component and a solvent. For example, the varnish is screen-printed on one surface of the metal supporting layer 2, and subsequently, heated, thereby forming a coating film including the first insulators 3A and 3B. Subsequently, the coating film is heated, thereby forming the first insulating layer 3.

1.2.3 Step [3]

In the step [3], as shown by a lower-side view of FIG. 1C, the first conductive layer 4 is formed. In the formation of the first conductive layer 4, a known conductive pattern forming method is used, and specifically, an additive method is used.

In the step [4], as shown in FIG. 1E, the second insulating layer 5 is formed. In the step [4], as shown in FIG. 1D, a film 50 is bonded to one surfaces of the metal supporting layer 2, the first insulating layer 3, and the first conductive layer 4 in the thickness direction.

The film 50 has flexibility. The film 50 has a thickness, and is along the plane direction. The film 50 is solid at room temperature, and has the other surface in the thickness direction which is plastically deformed by compressive bonding. The film 50 is made of a photosensitive resin (preferably, a photosensitive resin containing a photosensitive agent and a polyamic acid resin). The film 50 includes a photosensitive adhesive layer 501 and a photosensitive resin layer 502 in order toward one side in the thickness direction.

The photosensitive adhesive layer 501 forms the other surface of the film 50 in the thickness direction. The photosensitive adhesive layer 501 is an uncured layer before curing. Further, the photosensitive adhesive layer 501 is a unexposed layer before exposure. The photosensitive adhesive layer 501 contains an adhesive component constituting an adhesive, and a photosensitive agent.

The thickness of the photosensitive adhesive layer 501 is, for example, 1 μm or more, preferably 3 μm or more, and for example, 30 μm or less, preferably 20 μm or less. The ratio of the thickness of the photosensitive adhesive layer 501 to the thickness of the film 50 is, for example, 0.1 or more, preferably 0.3 or more, and for example, 0.9 or less, preferably 0.7 or less.

The photosensitive resin layer 502 forms one surface of the film 50 in the thickness direction. The photosensitive resin layer 502 is disposed on one surface of the photosensitive adhesive layer 501 in the thickness direction. The photosensitive resin layer 502 is an uncured layer before curing. Further, the photosensitive adhesive layer 501 is a unexposed layer before exposure. The photosensitive resin layer 502 contains a resin component (precursor material, preferably, polyamic acid resin) constituting a resin layer, and a photosensitive agent.

The thickness of the photosensitive resin layer 502 is, for example, 1 μm or more, preferably 3 μm or more, and for example, 30 μm or less, preferably 20 μm or less. The ratio of the thickness of the photosensitive resin layer 502 to the thickness of the film 50 is, for example, 0.1 or more, preferably 0.3 or more, and for example, 0.9 or less, preferably 0.7 or less.

The thickness of the film 50 is, for example, 3 μm or more, preferably 5 μm or more, and for example, 50 μm or less, preferably 30 μm or less.

As shown in a phantom line, a separator 53 may be disposed on each of one surface and the other surface of the film 50 in the thickness direction.

1.2.4 Step [4]

In the step [4], the above-described film 50 is compressively bonded to the metal supporting layer 2, the first insulating layer 3, and the first conductive layer 4. Specifically, each of the divided body 11A including the first insulator 3A and the first wiring 4A, and the divided body 11B including the first insulator 3B and the first wiring 4B is embedded by the film 50. In the step [4], the photosensitive adhesive layer 501 of the film 50 is in contact with one surface of the metal supporting layer 2 in the thickness direction, one surface of the first insulating layer 3 in the thickness direction, both end surfaces of the first insulating layer 3 in the width direction, one surface of the first conductive layer 4 in the thickness direction, and both end surfaces of the first conductive layer 4 in the width direction. In the step [4], a laminate consisting of the film 50, the metal supporting layer 2, the first insulating layer 3, and the first conductive layer 4 is compressively bonded using a laminator.

In the step [4], as shown in FIG. 1E, thereafter, the film 50 is exposed via a photomask (not shown), subsequently developed, and thereafter, heated after exposure, thereby forming the second insulating layer 5 having the second insulators 5A and 5B.

1.2.5 Step [5]

In the step [5], as shown in FIG. 1F, the second conductive layer 6 is formed. In the formation of the second conductive layer 6, a known conductive pattern forming method is used, and specifically, an additive method is used.

1.2.6 Step [6]

In the step [6], as shown in FIG. 1G, the third insulating layer 7 is formed. In the present embodiment, a varnish is coated onto one surfaces of the second insulating layer 5 and the second conductive layer 6 in the thickness direction to be exposed and developed, or pattern-printed, thereby forming a coating film.

When the varnish is coated, the varnish contains, for example, a photosensitive agent, a resin component, and a solvent. When the third insulating layer 7 is made of a polyimide resin, the resin component preferably contains an acid dianhydride and a diamine.

The varnish is coated onto one surfaces of the second insulating layer 5 and the second conductive layer 6, and subsequently heated, thereby forming a photosensitive coating film. The coating film contains a polyamic acid resin. The polyamic acid resin is a reactant of the acid dianhydride and the diamine, and is a precursor material of a polyimide resin. Subsequently, the coating film is exposed and developed, and, if necessary, heated after exposure, thereby forming the third insulating layer 7 including the third insulators 7A and 7B.

When the varnish is pattern-printed, the varnish contains, for example, the above-described resin component and a solvent. For example, the varnish is screen-printed on one surfaces of the second insulating layer 5 and the second conductive layer 6, and subsequently heated, thereby forming the third insulating layer 7 including the third insulators 7A and 7B.

Thus, the wiring circuit board 1 is produced.

### 2. Function and Effect of One Embodiment

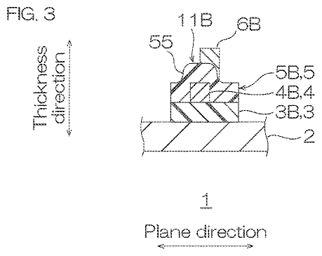

In the step [4], when the second insulating layer 5 is formed using the varnish, as shown in FIG. 3, an inclined portion 55 is easily formed on one surface of the second insulating layer 5 in the thickness direction. Then, thereafter, in the step [5], when the second wiring 6B is formed in the inclined portion 55, the dimensional accuracy of the second wiring 6B is lowered.

However, in the present embodiment, in the step [4], as shown in FIG. 1D, in the producing method, the film 50 made of a photosensitive resin is bonded to one surfaces of the first insulating layer 3 and the first conductive layer 4 in the thickness direction. Therefore, as shown in FIG. 1E, it is easy to flatten one surface of the second insulating layer 5 in the thickness direction. Therefore, it is possible to dispose the second conductive layer 6 with respect to the second insulating layer 5 with high dimensional accuracy.

Furthermore, as shown in FIG. 1D, the film 50 made of the photosensitive resin after being bonded to the first insulating layer 3 and the first conductive layer 4 is, as shown in FIG. 1E, patterned by exposure and development, and it is possible to easily form the second insulating layer 5.

Further, as shown in FIG. 1D, in the producing method, in the step [4], since the film 50 is compressively bonded to the first insulating layer 3 and the first conductive layer 4, it is possible to reliably flatten one surface of the second insulating layer 5 in the thickness direction.

In the producing method, it is possible to easily form the second insulating layer including the resin layer 52 made of a polyimide resin from the photosensitive polyamic acid resin by patterning.

In the producing method, since the film 50 further includes the adhesive layer 51 made of the photosensitive adhesive, it is possible to attach the resin layer 52 to the first insulating layer 3 via the adhesive layer 51, and further, it is possible to easily form the second insulating layer 5 by patterning the photosensitive film 50.

In the producing method, in the step [2], the first insulating layer 3 is formed by varnish coating, exposure, and development, or pattern printing, and in the step [4], the second insulating layer 5 is formed of the film 50 made of the photosensitive resin. Therefore, since the first insulating layer 3 can be formed thinly, it is possible to decrease the total thickness of the first insulating layer 3 and the second insulating layer 5.

In the producing method, it is possible to form the first insulating layer 3 made of the polyimide resin from the photosensitive polyamic acid resin.

In the producing method, since, as shown in FIG. 1G, in the step [6], the third insulating layer 7 is formed by varnish coating, exposure, and development, or pattern printing, and as shown in FIGS. 1C to 1E, in the step [4], the second insulating layer 5 is formed of the film made of the photosensitive resin, it is possible to thinly form the third insulating layer 7. Therefore, it is possible to decrease the total thickness of the third insulating layer 7 and the second insulating layer 5.

In the producing method, as shown in FIG. 1G, it is possible to form the third insulating layer 7 made of the polyimide resin from the photosensitive polyamic acid resin.

### 4. Modified Examples

In modified examples, the same reference numerals are provided for members and steps corresponding to each of those in one embodiment, and their detailed description is omitted. Further, the modified example can achieve the same function and effect as that of one embodiment unless otherwise specified. Furthermore, one embodiment and the modified examples thereof can be appropriately used in combination.

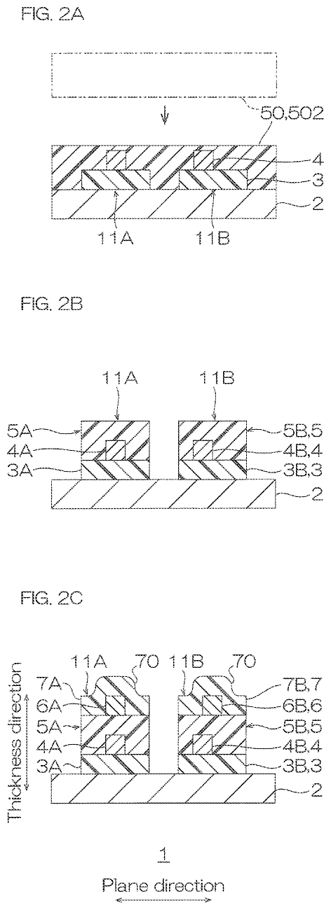

In this modified example, as shown by a virtual line of FIG. 2A, the film 50 does not include the photosensitive adhesive layer 501, and includes only the photosensitive resin layer 502. In the step [4], the film 50 consisting of the photosensitive resin layer 502 is bonded to one surfaces of the metal supporting layer 2, the first insulating layer 3, and the first conductive layer 4 in the thickness direction.

Thereafter, as shown in FIG. 2B, the film 50 consisting of the photosensitive resin layer 502 is exposed, developed, and heated after exposure, thereby forming the second insulating layer 5.

Thereafter, as shown in FIG. 2C, the step [5] and the step [6] are carried out in order, thereby forming the second conductive layer 6 and the third insulating layer 7 in order.

Although not shown, the photosensitive resin layer 502 may consist of a plurality of layers having different kinds in the thickness direction.

Although not shown, the first insulating layer 3 may be formed of a photosensitive film. In this case, a two-layer substrate in which the metal supporting layer 2 and the film are laminated is used.

The first insulating layer 3 and/or the third insulating layer 7 may be formed of the photosensitive film.

Although not shown, the adhesive may contain a polyimide resin adhesive. In the modified example, when the resin of the resin layer 52 is a polyimide resin, the material for the second insulating layer 5 is a polyimide resin.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### DESCRIPTION OF REFERENCE NUMERALS

1 Wiring circuit board
2 Metal supporting layer
3 First insulating layer
4 First conductive layer
5 Second insulating layer
6 Second conductive layer
7 Third insulating layer
50 Film
51 Adhesive layer
52 Resin layer
501 Photosensitive adhesive layer
502 Photosensitive resin layer

1. A method for producing a wiring circuit board, the wiring circuit board comprising:
a metal supporting layer,
a first insulating layer disposed on one surface of the metal supporting layer in a thickness direction,
a first conductive layer disposed on one surface of the first insulating layer in the thickness direction,
a second insulating layer disposed on one surface of the first insulating layer in the thickness direction so as to cover the first conductive layer, and
a second conductive layer disposed on one surface of the second insulating layer in the thickness direction, wherein
the method includes a step of forming the second insulating layer by bonding a film made of a photosensitive resin to one surfaces of the first insulating layer and the first conductive layer in the thickness direction.

2. The method for producing a wiring circuit board according to claim 1, wherein
in the step of forming the second insulating layer, the film is compressively bonded to the first insulating layer and the first conductive layer.

3. The method for producing a wiring circuit board according to claim 1, wherein
the film includes a photosensitive resin layer containing a polyamic acid resin.

4. The method for producing a wiring circuit board according to claim 3, wherein
the film further includes a photosensitive adhesive layer made of an adhesive.

5. The method for producing a wiring circuit board according to claim 1 further comprising:
a step of forming the first insulating layer by varnish coating, exposure, and development, or pattern printing.

6. The method for producing a wiring circuit board according to claim 1, wherein
the coating film formed by coating, exposure, and development, or pattern printing contains a polyamic acid resin.

7. The method for producing a wiring circuit board according to claim 1, wherein
the wiring circuit board further includes a third insulating layer disposed on one surface of the second insulating layer in the thickness direction so as to cover the second conductive layer, and
the method further includes a step of forming the third insulating layer by varnish coating, exposure, and development, or pattern printing.

8. The method for producing a wiring circuit board according to claim 7, wherein
a coating film formed by coating, exposure, and development, or pattern printing contains a polyamic acid resin.
